(19) United States
(12) Patent Application Publication
(10) Pub. No.: US 2024/0243726 A1
(43) Pub. Date: Jul. 18, 2024

(54) MULTI-PATH FILTER WITH ACOUSTIC WAVE RESONATORS

(71) Applicant: Skyworks Solutions, Inc., Irvine, CA (US)

(72) Inventors: Li Chen, Irvine, CA (US); Zhiyuan Ni, Irvine, CA (US); Wenrui Lin, Irvine, CA (US)

(21) Appl. No.: 18/545,866

(22) Filed: Dec. 19, 2023

Related U.S. Application Data
(60) Provisional application No. 63/479,913, filed on Jan. 13, 2023.
(60) Provisional application No. 63/479,817, filed on Jan. 13, 2023.

(51) Int. Cl. H03H 9/54; H03H 9/56; H04B 1/00

(52) U.S. Cl. CPC H03H 9/542; H03H 9/568; H04B 1/0057

(57) ABSTRACT

Aspects of this disclosure relate to a multi-path filter for filtering a radio frequency signal. The multi-path filter includes two signal paths from a node to an output port. The first signal path includes a series acoustic wave resonator. The second signal path includes a shunt acoustic wave resonator and a phase shifter. Related multiplexers, radio frequency modules, radio frequency systems, wireless communication devices, and methods are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/479,817, filed Jan. 13, 2023 and titled “MULTI-PATH FILTER WITH ACOUSTIC WAVE RESONATORS,” and U.S. Provisional Application No. 63/479,913, filed Jan. 13, 2023 and titled “MULTI-PATH FILTER FOR FILTERING RADIO FREQUENCY SIGNALS,” the disclosures of each of which are hereby incorporated by reference in their entireties and for all purposes.

### BACKGROUND

### Technical Field

The disclosed technology relates to filters that include acoustic wave resonators. Embodiments of this disclosure relate to multi-path filters for filtering radio frequency signals, where the multi-path filters include acoustic wave resonators.

### Description of Related Technology

Acoustic wave filters can be implemented in radio frequency electronic systems. For instance, filters in a radio frequency front end of a mobile phone can include one or more acoustic wave filters. A plurality of acoustic wave filters can be arranged as a multiplexer. For instance, two acoustic wave filters can be arranged as a diplexer.

An acoustic wave filter can include a plurality of acoustic resonators arranged to filter a radio frequency signal. Example acoustic wave filters include surface acoustic wave (SAW) filters and bulk acoustic wave (BAW) filters. BAW filters include BAW resonators. Example BAW resonators include film bulk acoustic wave resonators (FBARs) and BAW solidly mounted resonators (SMRs). In BAW resonators, acoustic waves propagate in a bulk of a piezoelectric layer.

Filters with relatively wide passbands and high out-of-band rejection can be desirable. There are technical challenges to implementing such filters with acoustic wave ladder filters while meeting design specifications.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a multi-path filter for filtering a radio frequency signal. The multi-path filter includes a first signal path and a second signal path. The first signal path is from a node of the multi-path filter to an output port of the multi-path filter. The first signal path includes a series acoustic wave resonator. The second signal path is from the node to the output port. The second signal path includes a shunt acoustic wave resonator and a phase shifter.

The multi-path filter can have a passband formed by at least a combined impedance response of the first signal path and the second signal path. The passband can span at least 800 megahertz. The passband can have a bandwidth that is at least 20% of a center frequency of the passband. The passband can corresponds to a fifth generation New Radio operating band. Impedances of the first signal path and the second signal path can cancel each other outside of the passband to form rejections.

The multi-path filter can have a rejection of at least 50 decibels for a Wi-Fi frequency band.

Frequency responses of the first signal path and the second signal path can combine in a passband of the multi-path filter. The frequency responses of the first signal path and the second signal path can cancel for a rejection band of the multi-path filter that is outside of the passband.

The phase shifter can include a transmission line and a capacitor. The phase shifter can include a coil inductor and a capacitor.

The multi-path filter can further include a second series acoustic wave resonator coupled between an input port of the multi-path filter and the node.

The multi-path filter can further include a second series acoustic wave resonator and a second shunt acoustic wave resonator. The phase shifter can be coupled between the second shunt acoustic wave resonator and the output port. The second series acoustic wave resonator can be coupled between the shunt acoustic wave resonator and the second shunt acoustic wave resonator.

The multi-path filter can further include a second shunt acoustic wave resonator coupled between the node and ground. The multi-path filter can further include a second series acoustic wave resonator in series with the series acoustic wave resonator.

The multi-path filter can be a receive filter.

The multi-path filter provides a single ended output signal to the output port.

The series acoustic wave resonator and the shunt acoustic wave resonator can be bulk acoustic wave resonators.

Another aspect of this disclosure is a multi-path filter for filtering a radio frequency signal. The multi-path filter includes a band pass section and an extractor section. The band pass section is coupled between an input port and an output port. The band pass section includes a series acoustic wave resonator. The extractor section includes a second acoustic wave resonator and a phase shifter. The second acoustic wave resonator and the phase shifter are in a signal path between the input port and the output port. The multi-path filter has a passband formed by at least a combined impedance response of the band pass section and the extractor section. The multi-path filter has a rejection band outside the passband that is formed by at least cancellation of impedance responses of the band pass section and the extractor section.

The multi-path filter can receive a single ended input signal at the input port and provide a single ended output signal to the output port.

The series acoustic wave resonator and the second acoustic wave resonator can be bulk acoustic wave resonators.

The multi-path filter can further include a shunt inductor electrically connected to the input port for input matching.

The multi-path filter can further include a series inductor electrically connected to the output port for output matching.

The multi-path filter can further include a second series acoustic wave resonator in series with the series acoustic wave resonator. The extractor section can be connected to a node between the series acoustic wave resonator and a second series acoustic wave resonator. The multi-path filter can further include a shunt acoustic wave resonator electrically connected between ground and a node between the series acoustic wave resonator and a second series acoustic wave resonator.

The extractor section can include a third acoustic wave resonator. The phase shifter can be coupled between the second shunt acoustic wave resonator and the output port.

The multi-path filter can be a receive filter.

The phase shifter can include a capacitor and a transmission line inductor. The phase shifter can include a capacitor, a coil inductor, and a transmission line inductor.

The passband can span at least 800 megahertz. The passband can have a bandwidth of at least 20% of a center frequency of the passband.

The rejection band can correspond to a Wi-Fi frequency band. The rejection band can have a rejection of at least 50 decibels.

The passband can correspond to a fifth generation New Radio operating band.

Another aspect of this disclosure is a multiplexer that includes a multi-path filter in accordance with any suitable principles and advantages disclosed herein and a second filter connected to the multi-path filter at a common node.

Another aspect of this disclosure is a radio frequency module that includes a multi-path filter in accordance with any suitable principles and advantages disclosed herein, radio frequency circuitry, and a package structure enclosing the multi-path filter and the radio frequency circuitry.

Another aspect of this disclosure is a radio frequency system that includes an antenna, a multi-path filter in accordance with any suitable principles and advantages disclosed herein, and an antenna switch configured to selectively electrically connect the antenna and a signal path that includes the multi-path filter

Another aspect of this disclosure is a wireless communication device that includes a radio frequency front end including a multi-path filter in accordance with any suitable principles and advantages disclosed herein, an antenna coupled to the radio frequency front end, a transceiver in communication with the radio frequency front end, and a baseband processor in communication with the transceiver.

Another aspect of this disclosure is a method of radio frequency signal processing. The method includes receiving a radio frequency signal via at least an antenna and filtering the radio frequency signal with a multi-path filter in accordance with any suitable principles and advantages disclosed herein.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

The present disclosure relates to U.S. patent application Ser. No. ______ [Attorney Docket SKYWRKS.1462A2], titled “MULTI-PATH FILTER FOR FILTERING RADIO FREQUENCY SIGNALS,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a schematic diagram of a multi-path filter according to an embodiment.

FIG. 1B is a graph of frequency response and phase of signal paths of the multi-path filter of FIG. 1A.

FIG. 2A is a schematic diagram of a multi-path filter according to an embodiment.

FIG. 2B is a graph of frequency response and phase difference for the multi-path filter of FIG. 2A.

FIG. 3 is a schematic diagram of a multi-path filter according to an embodiment.

FIG. 4A is a graph of frequency response of the multi-path filter of FIG. 3.

FIG. 4B is a graph of phase over frequency of the multi-path filter of FIG. 3.

FIG. 5A is a schematic diagram of a ladder filter.

FIG. 5B is a schematic diagram of a multi-path filter according to an embodiment.

FIG. 6A is a graph of frequency responses of the ladder filter of FIG. 5A and two versions of the multi-path filter of FIG. 5B. FIG. 6B is a Smith chart at an antenna port associated with the filters of FIGS. 5A and 5B. FIG. 6C is a Smith chart at a receive port associated with the filters of FIGS. 5A and 5B. FIG. 6D is graph of insertion loss in the passband associated with the filters of FIGS. 5A and 5B.

FIG. 7A is a schematic diagram of a radio frequency system that includes a multiplexer with acoustic wave ladder filters.

FIG. 7B is a schematic diagram of a radio frequency system that includes a multiplexer with a multi-path filter according to an embodiment.

FIG. 8A is a graph of frequency responses of a ladder filter of FIG. 7A and a multi-path filter of FIG. 7B. FIG. 8B is a Smith chart at an antenna port associated with the ladder filter of FIG. 7A and the multi-path filter of FIG. 7B. FIG. 8C is a Smith chart at a receive port associated with the ladder filter of FIG. 7A and the multi-path filter of FIG. 7B. FIG. 8D is graph of insertion loss in the passband associated with the ladder filter of FIG. 7A and the multi-path filter of FIG. 7B.

FIG. 9 is a schematic diagram of a multi-path filter with a band pass ladder stage according to an embodiment.

FIG. 10 is a schematic diagram of a multi-path filter with a band pass ladder stage and a plurality of shunt acoustic wave resonators coupled to a phase shifter according to an embodiment.

FIG. 11 is a schematic diagram of a multi-path filter with an example phase shifter according to an embodiment.

FIG. 12 is a schematic diagram of a multi-path filter with an example phase shifter according to an embodiment.

FIG. 13A is schematic diagram of a band pass filter. FIG. 13B is a schematic diagram of a diplexer that includes a multi-path filter according to an embodiment.

FIG. 13C is a schematic diagram of a multiplexer that includes a multi-path filter according to an embodiment. FIG. 13D is a schematic diagram of a multiplexer that includes a multi-path filter according to an embodiment. FIG. 13E is a schematic diagram of a multiplexer that includes a multi-path filter according to an embodiment.

FIGS. 14, 15, and 16 are schematic block diagrams of illustrative packaged modules according to certain embodiments.

FIG. 17 is a schematic diagram of one embodiment of a mobile device.

FIG. 18 is a schematic diagram of one example of a communication network.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Developments in fifth generation (5G) technology have created demanding specifications for sub-6 gigahertz (GHz) front-end modules that support sub-6 GHz bands, such as Band n77 and Band n79. Bands such as these can raise new filter design challenges due to their ultra-wide bandwidth and stringent intermodulation distortion (IMD) specifications. For example, Band n77 can have specifications for a band pass filter with a fractional bandwidth of 24% and out of band rejection of more than 50 decibels (dB) at low band (LB) and/or mid high band (MHB) and/or 5 GHz Wi-Fi frequencies.

While it is possible for a lumped element filter to meet all of the rejection specifications, the passband of such a filter can encounter relatively high insertion loss. Such insertion loss can make filter performance uncompetitive. Bulk acoustic wave (BAW) filters can achieve relatively high rejection without significant insertion loss trade-off. However, a BAW ladder filter stage may not provide sufficient acoustic rejection at high band (HB) and/or Wi-Fi frequency bands due to electromechanical coupling coefficient (kt²) limitations of BAW resonators. Accordingly, there is a desire for a new topology to increase the bandwidth of BAW filters and enable rejection above the BAW resonator kt² limit.

A Band n77 receive filter response can be implemented by a combination of a BAW ladder stage and lumped elements high pass configuration. Such a filter can meet most of the IMD specifications while providing a competitive noise figure (NF). As the rejection specification gets more difficult to meet, additional lumped elements may be implemented to deepen the rejection notches. This can worsen NF. Also, there are technical challenges for current filter designs meeting the out-of-band rejection specification at 5 GHZ Wi-Fi without severe NF trade-offs.

Aspects of this disclosure relate to a multi-path filter. The multi-path filter can be a dual-path filter for a single-ended application. The multi-path filter can include a band pass section and an extractor section. The band pass section can contribute to a passband of the multi-path filter. The band pass section can include at least a series acoustic wave resonator. The extractor section can provide an out of phase band stop profile. The extractor section can include a shunt acoustic wave resonator and a phase shifter in a signal path between a filter input port and a filter output port. The frequency responses of the band pass section and the extractor section can combine to form a relatively wide pass band. The band pass section and the extractor section can cancel each other outside of the passband and form rejections. This cancelation can involve mostly cancelling, almost completely cancelling, or completely cancelling. The multi-path filter can filter a radio frequency signal.

Multi-path filters disclosed herein can achieve advantages over other filters. Multi-path filters disclosed herein can provide a bandwidth and rejection profile beyond the electromechanical coupling coefficient (kt²) limitation of a BAW resonator in a ladder stage topology. Lattice filters can provide relatively wide bandwidth. However, lattice filters are often implemented with a transformer. Multi-path filters with phase shifters disclosed herein can implement single-ended multi-path filters. Such filters can achieve benefits of a lattice stage without the use of a balun. Multi-path filters disclosed herein can achieve rejection at frequencies where ladder designs have technical challenges achieving rejection (e.g., at HB, 5G Wi-Fi, etc.) while having comparable filter loss and lower resonator counts compared to ladder filters. Additional stages in a multi-path filter can be included as desired to improve rejection performance.

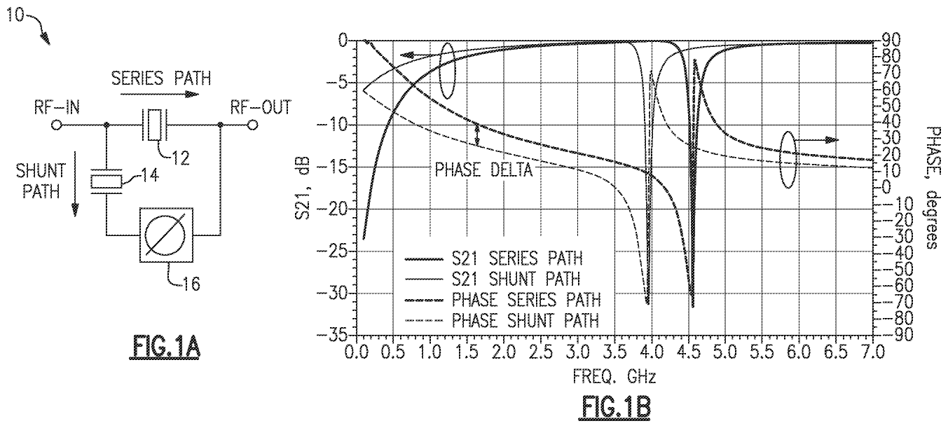

FIG. 1A is a schematic diagram of a multi-path filter 10 according to an embodiment. As illustrated, the multi-path filter 10 includes a first signal path including a series acoustic wave resonator 12 and a second signal path including a shunt acoustic wave resonator 14 and a phase shifter 16. The first signal path can be a series path, and the second signal path can be a shunt path. A radio frequency signal can be received at an input port RF_in of the multi-path filter 10. The radio frequency can propagate from the input port RF_in through both the first signal path and the second signal path to an output port RF_out of the multi-path filter 10. The multi-path filter 10 can be a receive filter where the input port RF_in can be an antenna port and the output port RF_out can be a receive port.

A multi-path filter can include two or more signal paths between an input port and an output port of the multi-path filter. The multi-path filter 10 is a dual path filter as illustrated. The multi-path filter 10 is arranged for a single-ended application with both a single-ended input and a single-ended output. The input port of the multi-path filter 10 can receive a single-ended input signal. The output port of the multi-path filter 10 can provide a single-ended output signal. In the multi-path filter 10, the first signal path includes a band pass section and the second signal path includes be an extractor section. A combined impedance of the band pass section and the extractor section can form a passband for the multi-path filter 10. The extractor section can generate a stop band outside of the passband. The phase shifter can shift phase such that (a) the extractor section has a frequency response that adds/combines with the frequency response of the band pass section to form the passband and (b) the extractor section has a frequency response that subtracts/cancels with the frequency response of the band pass section outside of the passband to increase rejection.

The series acoustic wave resonator 12 and the shunt acoustic wave resonator 14 can be any suitable acoustic wave resonators. The series acoustic wave resonator 12 can be a BAW resonator, a surface acoustic wave (SAW) resonator, a temperature-compensated SAW (TC SAW) resonator, a multilayer piezoelectric (MPS) SAW resonator, a boundary wave resonator, a Lamb wave resonator, or the like. The shunt acoustic wave resonator 14 can be a BAW resonator, a SAW resonator, a TC SAW resonator, a MPS SAW resonator, a boundary wave resonator, a Lamb wave resonator, or the like. In certain applications, the series acoustic wave resonator 12 and the shunt acoustic wave resonator 14 can be BAW resonators.

FIG. 1B is a graph of frequency response and phase of signal paths of the multi-path filter 10 of FIG. 1A. The multi-path filter 10 can include a series acoustic wave resonator 12 and a shunt acoustic wave resonator 14 that are similar except for the shunt acoustic wave resonator 14 having a resonant frequency that is approximately 500 megahertz (MHz) less than the series acoustic wave resonator 12. This difference in resonant frequency is reflected in FIG. 1B. FIG. 1B shows that the phase difference or phase delta between the first signal path and the second signal path is relatively consistent except near resonance.

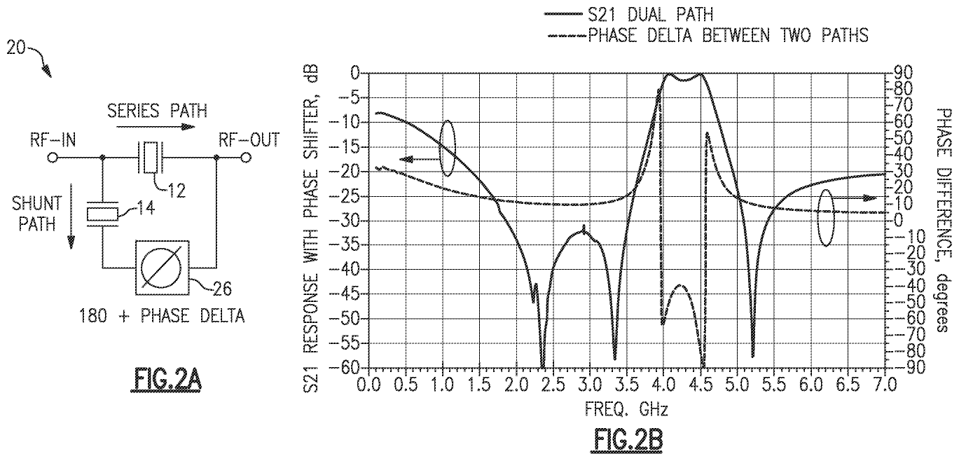

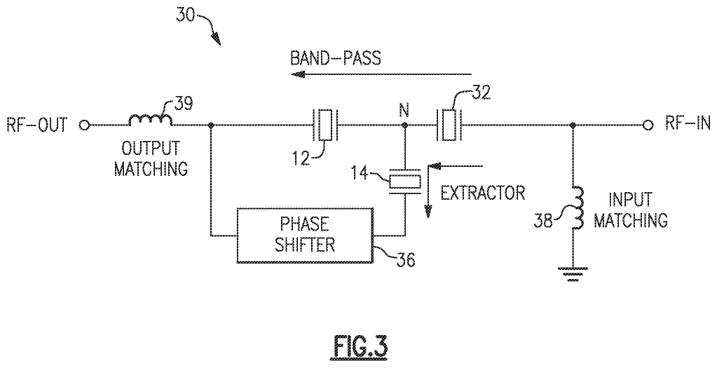

FIG. 2A is a schematic diagram of a multi-path filter 20 according to an embodiment. The multi-path filter 20 is like the multi-path filter 10 of FIG. 1A, except that a different phase shifter is included in the shunt path. The multi-path filter 20 includes a phase shifter 26 that can shift phase 180° plus a phase delta. Rejection should be created if the phase difference between the two path is close to 180°, but not exactly 180° due to slight impedance magnitude difference from a resonance difference (e.g., 500 MHz resonant frequency difference) between the shunt acoustic waver resonator 14 and the series acoustic wave resonator 12. Sharp notches can be created where impedance cancellation is near ideal. The shunt path can contribute to creating a passband with the phase shifter 26 flipping its impedance from band-stop to passband. Accordingly, bandwidth can be increased since S21 can based on combined impedance response of both the series path and the shunt path of the multi-path filter 20.

FIG. 2B is a graph of frequency response and phase difference for the multi-path filter 20 of FIG. 2A. The multi-path filter 20 can include a series acoustic wave resonator 12 and a shunt acoustic wave resonator that are similar except for the shunt acoustic wave resonator 14 having a resonant frequency that is 500 MHz less than the series acoustic wave resonator 12. The phase shifter 26 can perform phase shifting as discussed with reference to FIG. 2A. FIG. 2B shows the frequency response for the multi-path filter 20 of FIG. 2A where impedances of the series and shunt paths combine to form the passband and the shunt path forms a stop band outside of the passband.

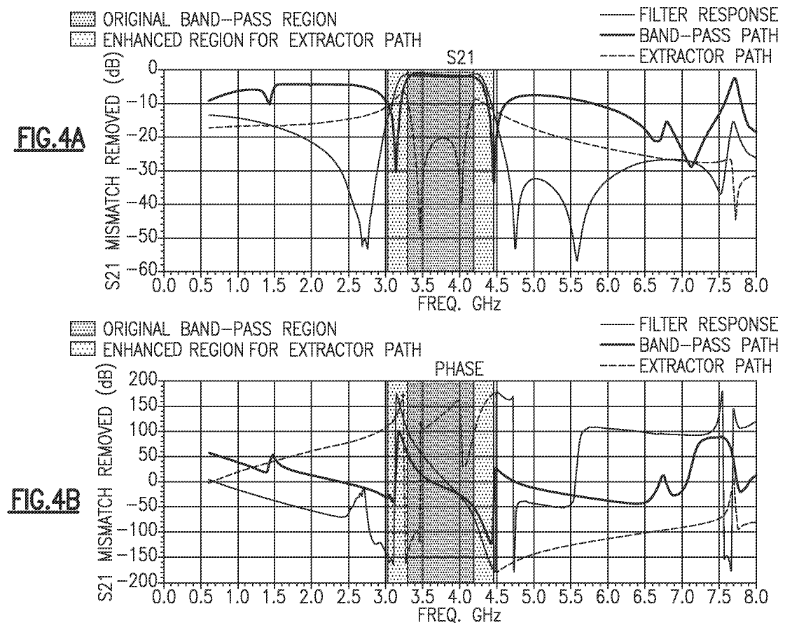

FIG. 3 is a schematic diagram of a multi-path filter 30 according to an embodiment. In the multi-path filter 30, a first series acoustic wave resonator 32 is coupled between an input port RF_in and a node N. The multi-path filter 30 includes two paths from the node N to an output port RF_out. The two paths of the multi-path filter 30 are a band pass path and an extractor path. The band pass path can have a band pass frequency response. The illustrated band pass path includes series acoustic wave resonator 12. The illustrated extractor path includes the shunt acoustic wave resonator 14 and the phase shifter 36. The extractor path can form an out of phase band stop profile. For in-band, the impedances of the band pass path and extractor paths can combine and form a relatively wide passband. For out-of-band, the band pass path and extractor path can cancel out each other and form rejections. The out-of-band cancellation for the multi-path filter 30 can involve subtracting a frequency response of the extractor path from the frequency response of the band pass path. This cancelation can involve mostly cancelling, almost completely cancelling, or completely cancelling. The phase shifter 36 can perform phase shifting such that the extractor path has these in-band and out-of-band phase relationships with the band pass path. The multi-path filter 30 also includes an input matching network 38 and an output matching network 39. The input matching network 38 can be or include a shunt inductor. The output matching network 39 can be or include a series inductor.

FIG. 4A is a graph of frequency response of the multi-path filter 30 of FIG. 3. FIG. 4B is a graph of phase over frequency of the multi-path filter 30 of FIG. 3. The graph in FIG. 4A shows the individual frequency responses of the band pass path and the extractor path. As shown in FIG. 4A, the extractor path extends the pass band of the filter relative to the band pass path alone. This can create a relatively wide passband.

Multi-path filters disclosed herein can have a bandwidth of at least 600 MHz. The bandwidth can be at least 800 MHZ. The bandwidth can be approximately 900 MHz. For example, the passband can correspond to Band n77, which spans from 3300 MHZ to 4200 MHz. The bandwidth can be in a range from 600 MHz to 1000 MHz. The relatively wide passband can be at least 12% of a center frequency of the passband. The relatively wide passband can be at least 20% of a center frequency of the passband. For example, the relatively wide passband can be 24% of a center frequency of the passband for a Band n77 filter. The relatively wide passband can be in a range from 12% to 30% of a center frequency of the passband.

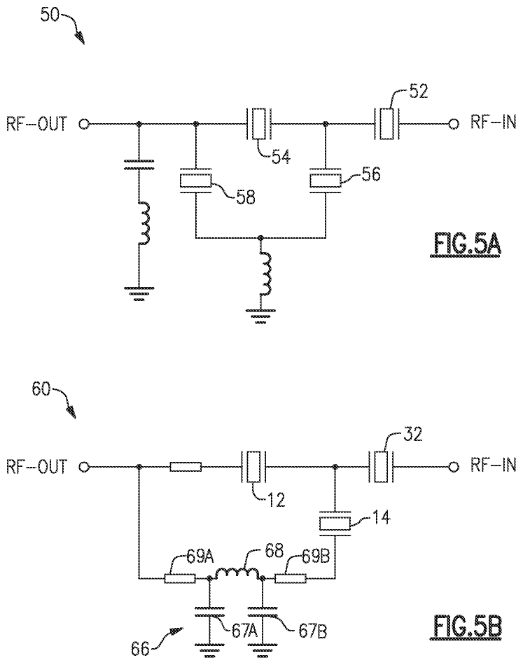

FIG. 5A is a schematic diagram of a ladder filter 50. The ladder filter includes series acoustic wave resonators 52 and 54 and shunt acoustic wave resonators 56 and 58.

FIG. 5B is a schematic diagram of a multi-path filter 60 according to an embodiment. The multi-path filter 60 is similar to the multi-path filter 30 of FIG. 3, except that the multi-path filter 60 includes a phase shifter 66 that includes capacitors 67A and 67B, a coil inductor 68, and transmission line inductors 69A and 69B. The phase shifter 66 is an example embodiment of a phase shifter for an extractor section. The acoustic wave resonators 12, 14, and 32 of the multi-path filter 60 can be BAW resonators in certain applications.

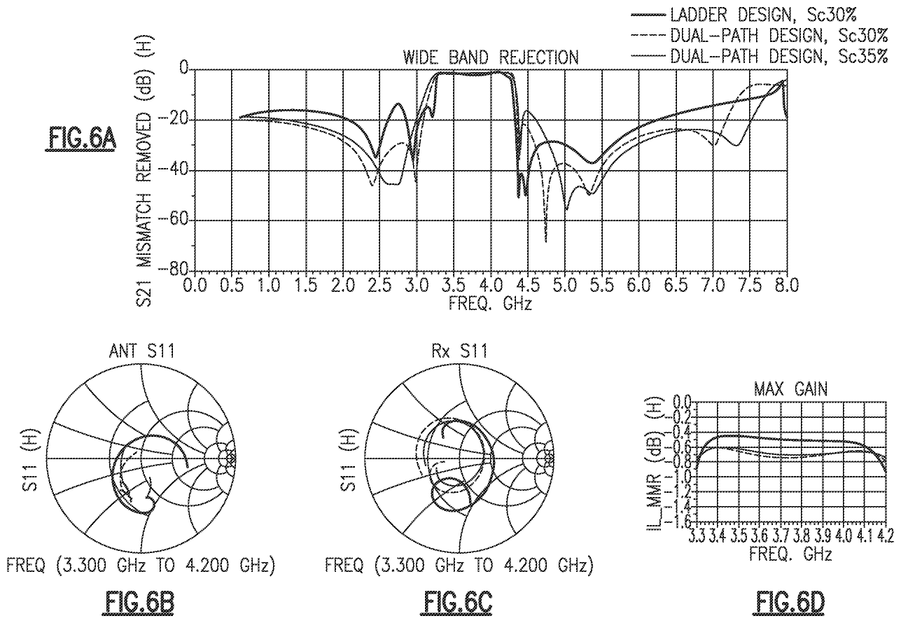

FIG. 6A is a graph of frequency responses of the ladder filter 50 of FIG. 5A and two versions of the multi-path filter 60 of FIG. 5B. These filters included BAW resonators with doped piezoelectric layers. The piezoelectric layers were aluminum nitride (AlN) piezoelectric layers doped with scandium (Sc). Two multipath filters 60 with different doping concentrations were simulated, one with 30% scandium and one with 35% scandium. FIG. 6A shows that ladder filter 50 can provide good insertion loss at mid channel due to the pure band pass design. However, edge roll off for the ladder filter 50 is faster than the multi-path filter 60. This can be due to electromechanical coupling coefficient kt² limitations of the BAW resonators of the ladder filter 50. FIG. 6A also shows that the multi-path filter 60 can provide a wider passband (with similar trim) relative to the ladder filter 50. In FIG. 6A, the notches in frequency response of the multi-path filter 60 can be created with acoustic and impedance cancellation. A higher doping concentration (e.g., of scandium) can pull acoustic rejection to HB and/or Wi-Fi frequencies in FIG. 6A. More generally, doping concentration can be adjusted to adjust acoustic rejection in the frequency domain.

The dual-path design of the multi-path filter 60 can depend on accurate impedance cancellation for the rejection being created at particular frequencies. Accordingly, multi-chip module design can be significant for implementing such impedance cancellation. Filter sections were simulated for a full module with 50 Ohm input/output terminations. Smith charts and a graph for insertion loss for the same filters as FIG. 6A are shown in FIGS. 6B, 6C, and 6D. FIG. 6B is a Smith chart at an antenna port. FIG. 6C is a Smith chart at a receive port. FIG. 6D is graph of insertion loss.

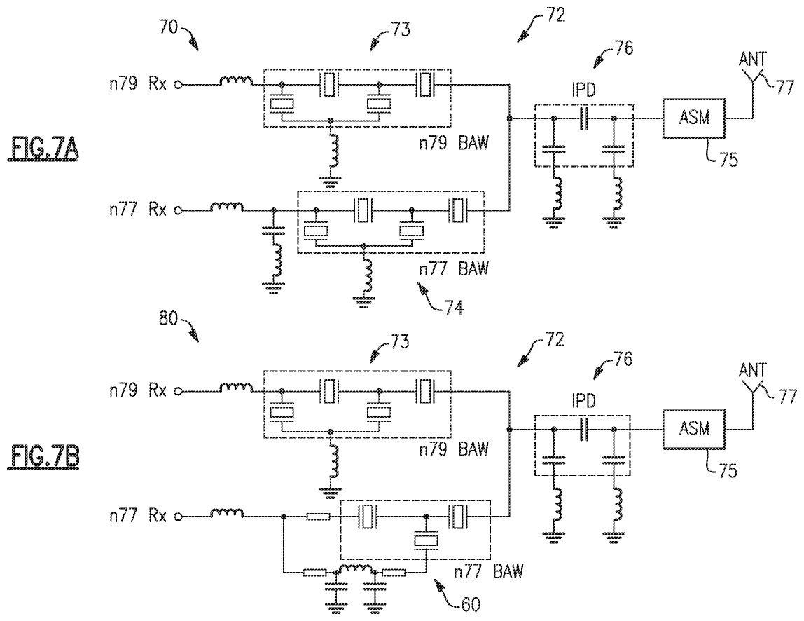

FIG. 7A is a schematic diagram of a radio frequency system 70 that includes a multiplexer 72 with acoustic wave ladder filters 73 and 74. In the radio frequency system 70, the multiplexer 72 is coupled to an antenna switch 75 by way of an impedance network 76. The antenna switch 75 can selectively electrically connect an antenna 77 to the multiplexer 72 As illustrated, the multiplexer 72 includes a Band n79 receive filter and a Band 77 receive filter. The acoustic wave ladder filters 73 and 74 can each include BAW resonators. The impedance network 76 can include integrated pass device (IPD) capacitors. The impedance network 76 can also include shunt inductors.

FIG. 7B is a schematic diagram of a radio frequency system 80 that includes a multiplexer 82 with a multi-path filter 60 according to an embodiment. The multi-path filter 60 is arranged as a Band n77 receive filter in the radio frequency system 80. The radio frequency system 80 is otherwise similar to the radio frequency system 70 of FIG. 7A.

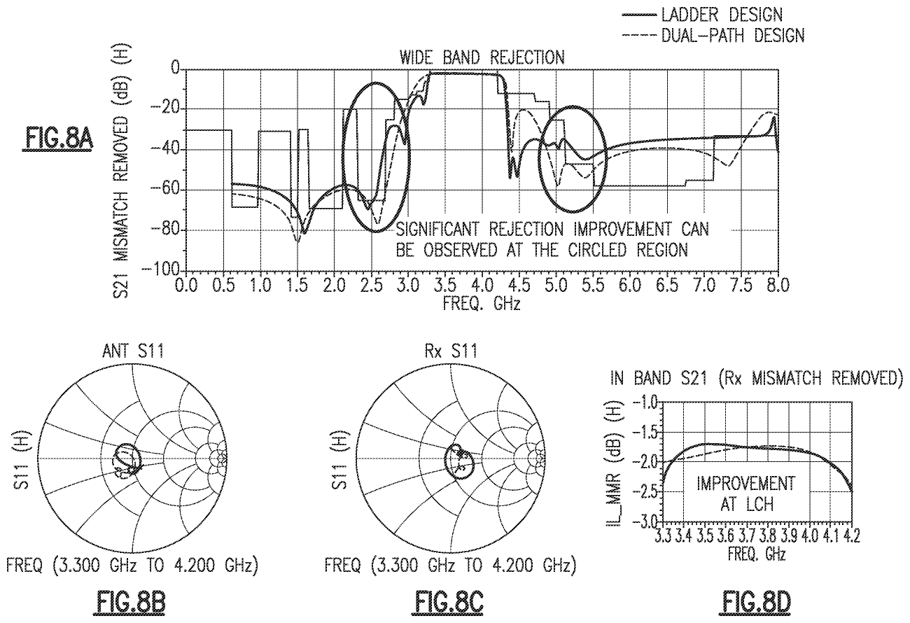

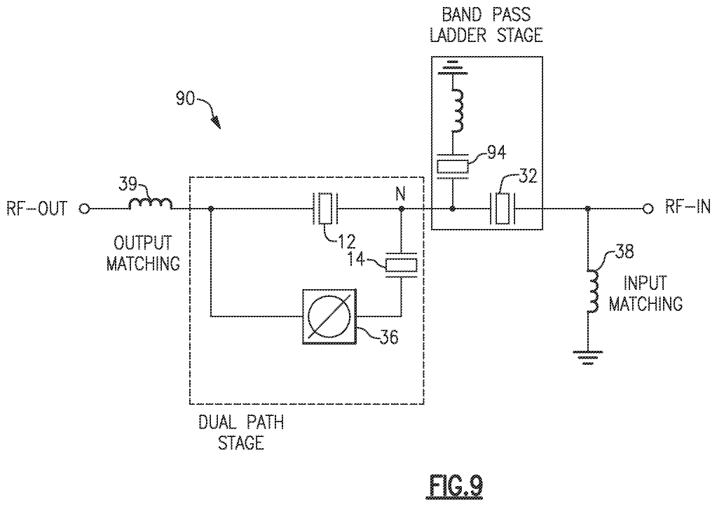

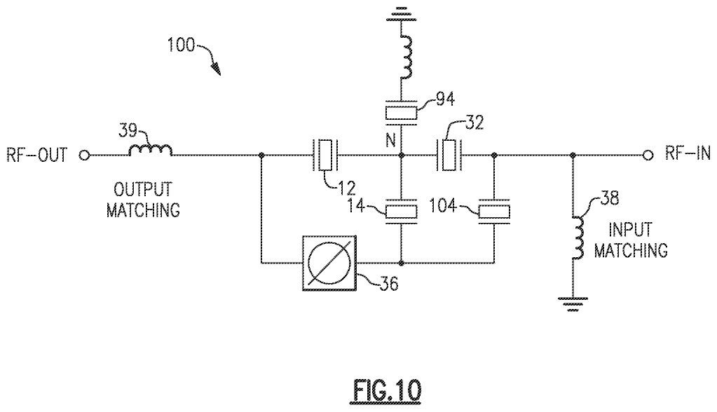

FIG. 8A is a graph of frequency responses of an acoustic wave ladder filter 74 of FIG. 7A and a multi-path filter 60 of FIG. 7B. This graph corresponds to a full module simulation. FIG. 8A shows significant rejection improvement in the circled regions for the multi-path filter 60 compared to the acoustic wave ladder filter 74. This graph indicates that the multi-path filter 60 can provide significantly better rejection at both 2.4 GHz Wi-Fi and 5 GHz Wi-Fi bands than the acoustic wave ladder filter 74. In FIG. 8A, the multi-path filter 60 also has a wider passband than the acoustic wave ladder filter 74. For the simulations, the receive ports were terminated with a low noise amplifier input impedance.

FIG. 8B is a Smith chart for an antenna port with curves for the acoustic wave ladder filter 74 of FIG. 7A and the multi-path filter 60 of FIG. 7B. FIG. 8C is a Smith chart for a receive port with curves for the acoustic wave ladder filter 74 of FIG. 7A and the multi-path filter 60 of FIG. 7B. FIG. 8D is graph of insertion loss in the passband for the acoustic wave ladder filter 74 of FIG. 7A and the multi-path filter 60 of FIG. 7B with receive mismatch removed. FIG. 8D indicates insertion loos improvement at the lower channel of the passband of the multi-path filter 60 compared to the acoustic wave ladder filter 74.

FIG. 9 is a schematic diagram of a multi-path filter 90 with a band pass ladder stage according to an embodiment. The multi-path filter 90 includes a band pass ladder stage and a dual path stage. The band pass ladder stage and the dual path stages are cascaded in the multi-path filter 90. The band pass ladder stage includes series acoustic wave resonator 32 and shunt acoustic wave resonator 94. The shunt acoustic wave resonator 94 is connected between the node N and ground. The dual path stage includes two signal paths between a node N and an output port RF_out: (1) a series path that includes the series acoustic wave resonator 12 and (2) shunt path that includes shunt acoustic wave resonator 14 and phase shifter 36. Although one band pass ladder stage is illustrated in some embodiments, two or more band pass ladder stages can be implemented in certain applications.

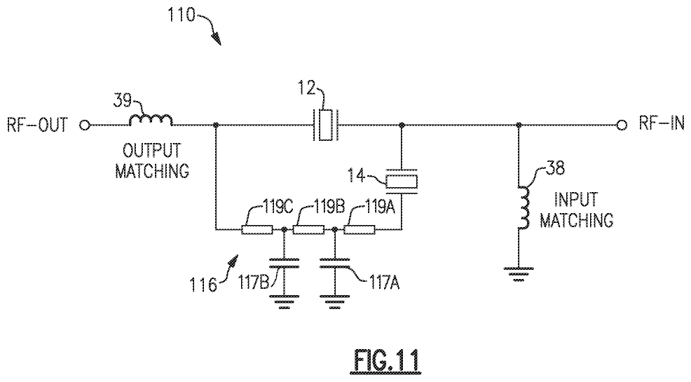

FIG. 10 is a schematic diagram of a multi-path filter 100 with a band pass ladder stage and a plurality of shunt acoustic wave resonators 14 and 104 coupled to a phase shifter 36 according to an embodiment. The multi-path filter 100 includes two shunt acoustic wave resonators 14 and 104 coupled between an input port RF_in of the multi-path filter 100 and the output port RF_out of the multi-path filter 100 by way of the phase shifter 36.

The extractor section of the multi-path filter 100 includes the shunt acoustic wave resonators 14 and 104 and the phase shifter 36. In some other applications, three or more shunt acoustic wave resonators can be included in an extractor section of a multi-path filter. In the multi-path filter 100, a single phase shifter 36 is coupled between both shunt acoustic wave resonators 14 and 104 and the output port RF_out. In some other applications, different shunt resonators of an exactor section can be coupled to an output port by way of different respective phase shifters.

The band pass ladder stage of the multi-path filter 100 includes (1) a series acoustic wave resonator 32 coupled between the shunt acoustic wave resonators 104 and 14 and (2) a shunt acoustic wave resonator 94 coupled to an electrode of the series acoustic wave resonator 14.

In the multi-path filter 100, there is a series acoustic wave resonator 12 coupled between node N and the output port RF_out. There is also a shunt path from the node N to the output port RF_out through the shunt acoustic wave resonator 14 and the phase shifter 36. The frequency response of the multi-path filter 100 can be created by extractor section mixing with an interstage band pass ladder stage. The multi-path filter 100 can be referred to as a hybrid multi-path ladder filter.

FIG. 11 is a schematic diagram of a multi-path filter 110 with an example phase shifter 116 according to an embodiment. The multi-path filter 110 includes a series path that includes the series acoustic wave resonator 12 and a shunt path that includes the shunt acoustic wave resonator 14 and the phase shifter 116. The phase shifter 116 is an example embodiment of the phase shifters 16, 26, and 36. The phase shifter 116 includes transmission line inductors 119A, 119B, and 119C and capacitors 117A and 117B. In the phase shifter 116, the transmission line inductors 119A, 119B, and 119C are arranged in series and the capacitors 117A and 117B are arranged in shunt. The phase shifter 116 can implement any suitable phase shifting disclosed herein. The capacitances of the capacitors 117A and 117B and the inductances of the inductors 119A, 119B, and 119C can implement such phase shifter. The phase shifter 116 can include a ladder network with shunt capacitors 117A and 117B and series transmission line inductors 119A, 119B, and 119C. Phase shifting disclosed herein can be implemented by shunt capacitors and series inductors in certain applications.

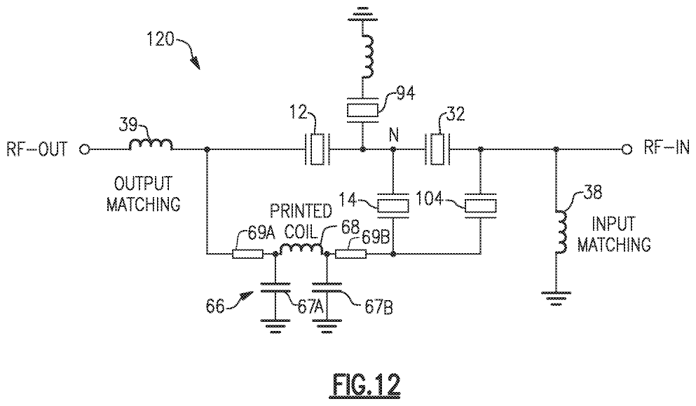

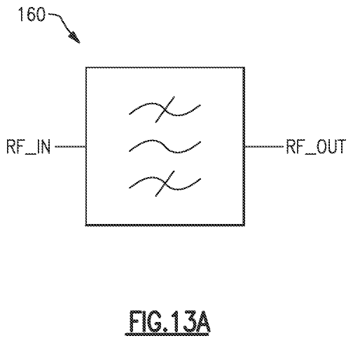

FIG. 12 is a schematic diagram of a multi-path filter 120 with an example phase shifter 66 according to an embodiment. The multi-path filter 120 is like the multi-path filter 100 of FIG. 10 where the phase shifter 36 is implemented by the phase shifter 66. The phase shifter 66 is an example embodiment of the phase shifters 16, 26, and 36. The phase shifter 66 is like the phase shifter 116 of FIG. 11, except that the phase shifter 66 includes a coil inductor 68. The coil inductor 68 can be a printed coil inductor. The phase shifter 66 includes a coil inductor 68 in place of one transmission line inductor 119B of the phase shifter 116. In some other applications, two or more inductors of a phase shifter of a multi-path filter can include coil inductors. Phase shifters can include any suitable capacitor(s) and any suitable inductor(s) to implement the phase shifting functionality disclosed herein for multi-path filters.

Acoustic wave filters disclosed herein can be arranged to filter a radio frequency signal. In certain applications, the acoustic wave filters can be band pass filters arranged to pass a radio frequency band and attenuate frequencies outside of the radio frequency band.

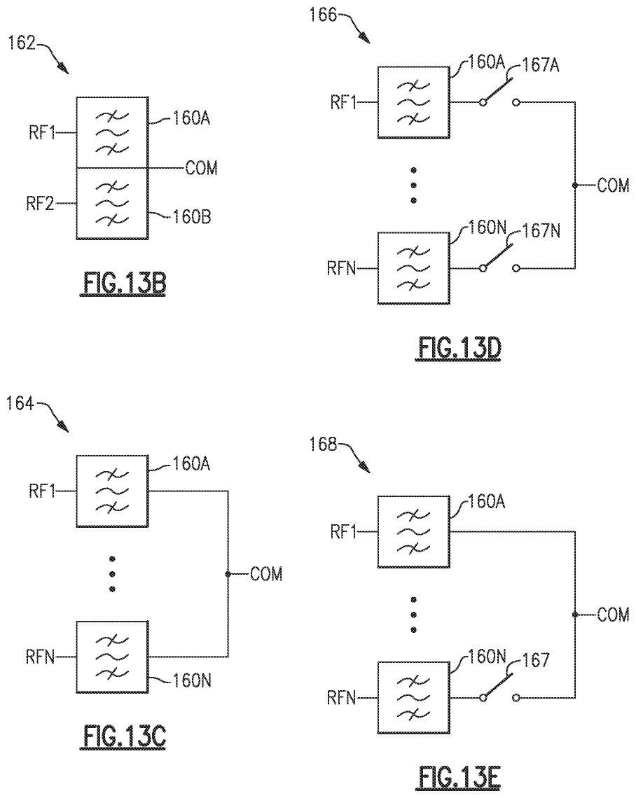

The principles and advantages disclosed herein can be implemented in a standalone filter and/or in one or more filters in any suitable multiplexer. The filter can be a band pass filter arranged to filter a fourth generation (4G) Long Term Evolution (LTE) band and/or a fifth generation (5G) New Radio (NR) band. Any suitable principles and advantages disclosed herein can be implemented in a receive filter. Any suitable principles and advantages disclosed herein can be implemented in a transmit filter. In some applications, two or more filters of a multiplexer can be implemented in accordance with any suitable principles and advantages disclosed herein. Examples of a standalone filter and multiplexers will be discussed with reference to FIGS. 13A to 13E. Any suitable principles and advantages of these filters and/or multiplexers can be implemented together with each other.

FIG. 13A is schematic diagram of an acoustic wave filter 160. The acoustic wave filter 160 can be implemented in accordance with any suitable principles and advantages disclosed herein. The acoustic wave filter 160 is a band pass filter. The acoustic wave filter 160 is arranged to filter a radio frequency signal. The acoustic wave filter 160 includes one or more acoustic wave devices coupled between a first input/output port RF_IN and a second input/output port RF_OUT. The acoustic wave filter 160 includes a relatively wide pass band and rejection outside of the passband.

Embodiments disclosed herein can be implemented in a standalone filter and/or in a filter of any suitable multiplexer. The filter can be a band pass filter arranged to filter a 4G LTE band and/or 5G NR band. Example multiplexers will be discussed with reference to FIGS. 13B to 13E. Any suitable principles and advantages of these multiplexers can be implemented together with each other.

FIG. 13B is a schematic diagram of a diplexer 162 that includes a multi-path filter according to an embodiment. The diplexer 162 includes a first filter 160A and a second filter 160B coupled to together at a common node COM. One of the filters of the diplexer 162 can be a transmit filter and the other of the filters of the diplexer 162 can be a receive filter. In some other instances, such as in a diversity receive application, the diplexer 162 can include two receive filters. Alternatively, the diplexer 162 can include two transmit filters. The common node COM can be an antenna node.

The first filter 160A is an acoustic wave filter arranged to filter a radio frequency signal. The first filter 160A includes one or more acoustic wave resonators coupled between a first radio frequency node RF1 and the common node COM. The first radio frequency node RF1 can be a transmit node or a receive node. The first filter 160A is a multi-path filter in accordance with any suitable principles and advantages disclosed herein.

The second filter 160B can be any suitable filter arranged to filter a second radio frequency signal. The second filter 160B can be, for example, an acoustic wave filter, a multi-path filter in accordance with any suitable principles and advantages disclosed herein, an LC filter, a hybrid acoustic wave LC filter, or the like. The second filter 160B is coupled between a second radio frequency node RF2 and the common node. The second radio frequency node RF2 can be a transmit node or a receive node.

Although example embodiments may be discussed with filters or diplexers for illustrative purposes, any suitable principles and advantages disclosed herein can be implemented in a multiplexer that includes a plurality of filters coupled together at a common node. Examples of multiplexers include but are not limited to a diplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can be implemented in accordance with any suitable principles and advantages disclosed herein.

FIG. 13C is a schematic diagram of a multiplexer 164 that includes a multi-path filter according to an embodiment. The multiplexer 164 includes a plurality of filters 160A to 160N coupled together at a common node COM. The plurality of filters can include any suitable number of filters including, for example, 3 filters, 4 filters, 5 filters, 6 filters, 7 filters, 8 filters, or more filters. Some or all of the plurality of filters can be acoustic wave filters. As illustrated, the filters 160A to 160N each have a fixed electrical connection to the common node COM. This can be referred to as hard multiplexing or fixed multiplexing. Filters have fixed electrical connections to the common node in hard multiplexing applications.

The first filter 160A is an acoustic wave filter arranged to filter a radio frequency signal. The first filter 160A can include one or more acoustic wave devices coupled between a first radio frequency node RF1 and the common node COM. The first radio frequency node RF1 can be a transmit node or a receive node. The first filter 160A is a multi-path filter in accordance with any suitable principles and advantages disclosed herein. The other filter(s) of the multiplexer 164 can include one or more acoustic wave filters, one or more multi-path filters in accordance with any suitable principles and advantages disclosed herein, one or more LC filters, one or more hybrid acoustic wave LC filters, the like, or any suitable combination thereof.

FIG. 13D is a schematic diagram of a multiplexer 166 that includes a multi-path filter according to an embodiment. The multiplexer 166 is like the multiplexer 164 of FIG. 13C, except that the multiplexer 166 implements switched multiplexing. In switched multiplexing, a filter is coupled to a common node via a switch. In the multiplexer 166, the switches 167A to 167N can selectively electrically connect respective filters 160A to 160N to the common node COM. For example, the switch 167A can selectively electrically connect the first filter 160A the common node COM via the switch 167A. Any suitable number of the switches 167A to 167N can electrically a respective filter 160A to 160N to the common node COM in a given state. Similarly, any suitable number of the switches 167A to 167N can electrically isolate a respective filter 160A to 160N to the common node COM in a given state. The functionality of the switches 167A to 167N can support various carrier aggregations.

FIG. 13E is a schematic diagram of a multiplexer 168 that includes a multi-path filter according to an embodiment. The multiplexer 168 illustrates that a multiplexer can include any suitable combination of hard multiplexed and switched multiplexed filters. One or more acoustic wave filters in accordance with any suitable principles and advantages disclosed herein can be a filter (e.g., the filter 160A) that is hard multiplexed to the common node COM of the multiplexer 168. Alternatively or additionally, one or more acoustic wave filters in accordance with any suitable principles and advantages disclosed herein can be a filter (e.g., the filter 160N) that is switch multiplexed to the common node COM of the multiplexer 168.

Multi-path filters disclosed herein can be implemented in a variety of packaged modules. Some example packaged modules will now be disclosed in which any suitable principles and advantages of the multi-path filters disclosed herein can be implemented. The example packaged modules can include a package that encloses the illustrated circuit elements. A module that includes a radio frequency component can be referred to as a radio frequency module. The radio frequency component can be referred to as radio frequency circuitry. The illustrated circuit elements can be positioned on a common packaging substrate. The packaging substrate can be a laminate substrate, for example. FIGS. 14 to 16 are schematic block diagrams of illustrative packaged modules according to certain embodiments. Any suitable combination of features of these packaged modules can be implemented with each other.

FIG. 14 is a schematic diagram of a radio frequency module 170 that includes an acoustic wave component 172 according to an embodiment. The illustrated radio frequency module 170 includes the acoustic wave component 172 and other circuitry 173. The acoustic wave component 172 can include acoustic wave devices 174 of a filter, for example. The acoustic wave devices 174 can be BAW devices in certain applications.

The acoustic wave component 172 shown in FIG. 14 includes acoustic wave devices 174 and terminals 175A and 175B. The acoustic wave devices 174 can be included in a multi-path filter in accordance with any suitable principles and advantages disclosed herein. The terminals 175A and 174B can serve, for example, as an input contact and an output contact. Although two terminals are illustrated, any suitable number of terminals can be implemented for a particular application. The acoustic wave component 172 and the other circuitry 173 are on a common packaging substrate 176 in FIG. 14. The packaging substrate 176 can be a laminate substrate. The terminals 175A and 175B can be electrically connected to contacts 177A and 177B, respectively, on the packaging substrate 176 by way of electrical connectors 178A and 178B, respectively. The electrical connectors 178A and 178B can be bumps or wire bonds, for example.

The other circuitry 173 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 173 can include one or more radio frequency circuit elements. The other circuitry 173 can be referred to as radio frequency circuitry in certain applications. The other circuitry 173 can be electrically connected to the acoustic wave devices 174. The radio frequency module 170 can include one or more packaging structures to, for example, provide protection and/or facilitate easier handling of the radio frequency module 170. Such a packaging structure can include an overmold structure formed over the packaging substrate 176. The overmold structure can encapsulate some or all of the components of the radio frequency module 170.

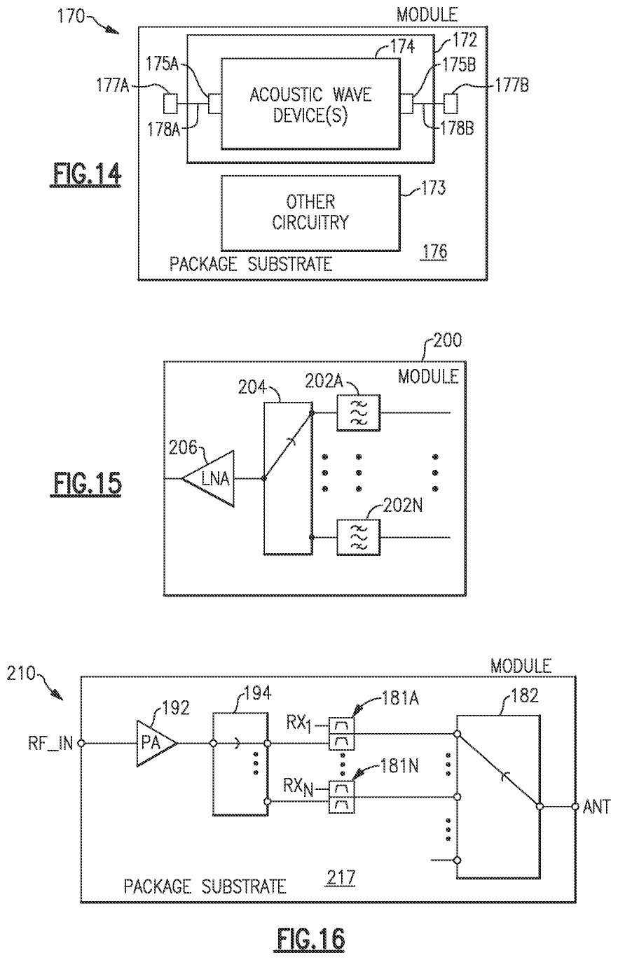

FIG. 15 is a schematic block diagram of a module 200 that includes filters 202A to 202N, a radio frequency switch 204, and a low noise amplifier 206 according to an embodiment. One or more filters of the filters 202A to 202N can be implemented in accordance with any suitable principles and advantages disclosed herein. Any suitable number of filters 202A to 202N can be implemented. The illustrated filters 202A to 202N are receive filters. One or more of the filters 202A to 202N can be included in a multiplexer that also includes a transmit filter and/or another receive filter. The radio frequency switch 204 can be a multi-throw radio frequency switch. The radio frequency switch 204 can electrically couple an output of a selected filter of filters 202A to 202N to the low noise amplifier 206. In some embodiments, a plurality of low noise amplifiers can be implemented. The module 200 can include diversity receive features in certain applications.

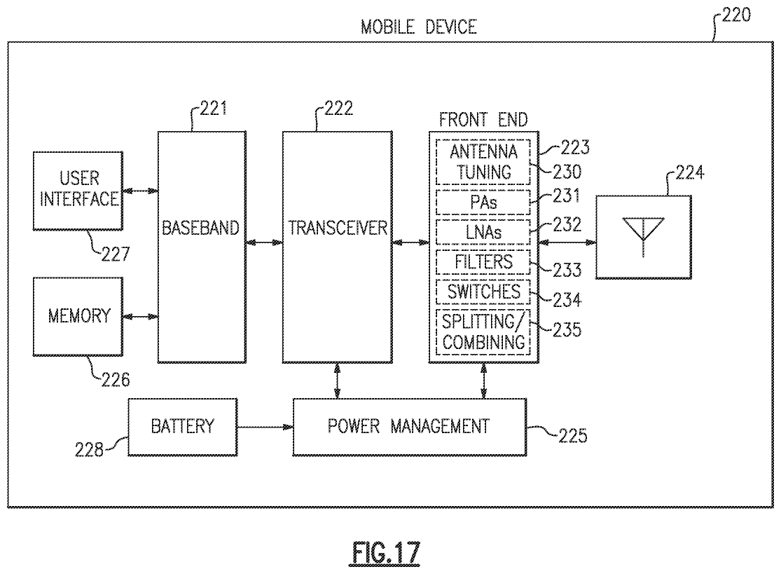

FIG. 16 is a schematic diagram of a radio frequency module 210 that includes a multi-path filter. As illustrated, the radio frequency module 210 includes diplexers 181A to 181N, a power amplifier 192, a radio frequency switch 194 configured as a select switch, and an antenna switch 182. The radio frequency module 210 can include a package that encloses the illustrated elements. The illustrated elements can be disposed on a common packaging substrate 217. The packaging substrate 217 can be a laminate substrate, for example. A radio frequency module that includes a power amplifier can be referred to as a power amplifier module. A radio frequency module can include a subset of the elements illustrated in FIG. 16 and/or additional elements.

The diplexers 181A to 181N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the receive filters can be a multi-path filter in accordance with any suitable principles and advantages disclosed herein. Alternatively or additionally, one or more of the transmit filters can be a multi-path filter in accordance with any suitable principles and advantages disclosed herein. Although FIG. 16 illustrates diplexers, any suitable principles and advantages disclosed herein can be implemented in other multiplexers (e.g., quadplexers, hexaplexers, octoplexers, etc.) and/or in switched multiplexers and/or with standalone filters.

The power amplifier 192 can amplify a radio frequency signal. The illustrated radio frequency switch 194 is a multi-throw radio frequency switch. The radio frequency switch 194 can electrically couple an output of the power amplifier 192 to a selected transmit filter of the transmit filters of the diplexers 181A to 181N. In some instances, the radio frequency switch 194 can electrically connect the output of the power amplifier 192 to more than one of the transmit filters. The antenna switch 182 can selectively couple a signal from one or more of the diplexers 181A to 181N to an antenna port ANT. The diplexers 181A to 181N can be associated with different frequency bands and/or different modes of operation (e.g., different power modes, different signaling modes, etc.).

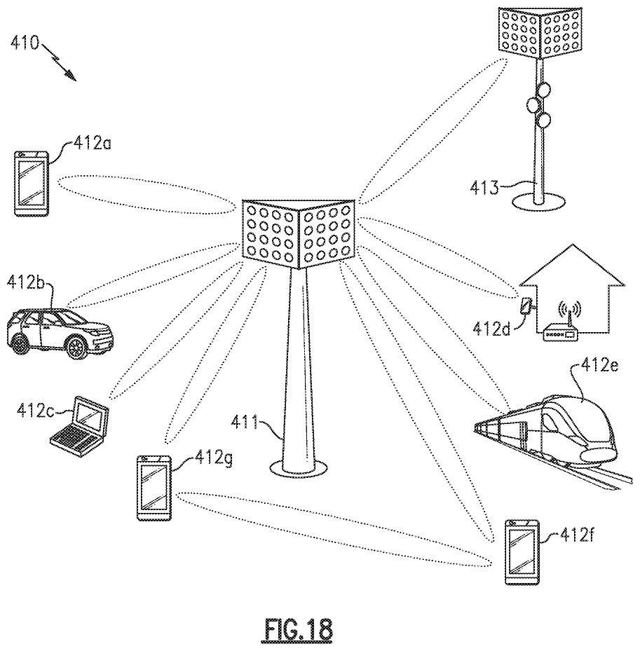

The multi-path filters disclosed herein can be implemented in wireless communication devices. FIG. 17 is a schematic block diagram of a wireless communication device 220 that includes a multi-path filter according to an embodiment. The wireless communication device 220 can be a mobile device. The wireless communication device 220 can be any suitable wireless communication device. For instance, a wireless communication device 220 can be a mobile phone, such as a smart phone. As illustrated, the wireless communication device 220 includes a baseband system 221, a transceiver 222, a front end system 223, one or more antennas 224, a power management system 225, a memory 226, a user interface 227, and a battery 228.

The wireless communication device 220 can be used to communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 222 generates RF signals for transmission and processes incoming RF signals received from the antennas 224. Various functionalities associated with the transmission and receiving of RF signals can be achieved by one or more components that are collectively represented in FIG. 17 as the transceiver 222. In one example, separate components (for instance, separate circuits or dies) can be provided for handling certain types of RF signals.

The front end system 223 aids in conditioning signals provided to and/or received from the antennas 224. In the illustrated embodiment, the front end system 223 includes antenna tuning circuitry 230, power amplifiers (PAS) 231, low noise amplifiers (LNAs) 232, filters 233, switches 234, and signal splitting/combining circuitry 235. However, other implementations are possible. The filters 233 can include one or more multi-path filters in accordance with any suitable principles and advantages disclosed herein.

The front end system 223 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 220 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 224 can include antennas used for a wide variety of types of communications. For example, the antennas 224 can include antennas for transmitting and/or receiving signals associated with a wide variety of frequencies and communications standards.

In certain implementations, the antennas 224 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 220 can operate with beamforming in certain implementations. For example, the front end system 223 can include amplifiers having controllable gain and phase shifters having controllable phase to provide beam formation and directivity for transmission and/or reception of signals using the antennas 224. For example, in the context of signal transmission, the amplitude and phases of the transmit signals provided to the antennas 224 are controlled such that radiated signals from the antennas 224 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 224 from a particular direction. In certain implementations, the antennas 224 include one or more arrays of antenna elements to enhance beamforming.

The baseband system 221 is coupled to the user interface 227 to facilitate processing of various user input and output (I/O), such as voice and data. The baseband system 221 can include a baseband processor. The baseband system 221 provides the transceiver 222 with digital representations of transmit signals, which the transceiver 222 processes to generate RF signals for transmission. The baseband system 221 also processes digital representations of received signals provided by the transceiver 222. As shown in FIG. 17, the baseband system 221 is coupled to the memory 226 of facilitate operation of the wireless communication device 220.

The memory 226 can be used for a wide variety of purposes, such as storing data and/or instructions to facilitate the operation of the wireless communication device 220 and/or to provide storage of user information.

The power management system 225 provides a number of power management functions of the wireless communication device 220. In certain implementations, the power management system 225 includes a PA supply control circuit that controls the supply voltages of the power amplifiers 231. For example, the power management system 225 can be configured to change the supply voltage(s) provided to one or more of the power amplifiers 231 to improve efficiency, such as power added efficiency (PAE).

As shown in FIG. 17, the power management system 225 receives a battery voltage from the battery 228. The battery 228 can be any suitable battery for use in the wireless communication device 220, including, for example, a lithium-ion battery.

Technology disclosed herein can be implemented in filters with acoustic wave resonators in 5G applications. 5G technology is also referred to herein as 5G New Radio (NR). 5G NR supports and/or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR. A multi-path filter including any suitable combination of features disclosed herein can be arranged to filter a radio frequency signal in a 5G NR operating band within Frequency Range 1 (FR1). FR1 can be from 410 MHz to 7.125 GHZ, for example, as specified in a current 5G NR specification. A multi-path filter in accordance with any suitable principles and advantages disclosed herein can be arranged to filter a radio frequency signal in a fourth generation (4G) Long Term Evolution (LTE). An acoustic wave filter in accordance with any suitable principles and advantages disclosed herein can have a pass band that includes a 4G LTE operating band and a 5G NR operating band. Such a filter can be implemented in a dual connectivity application, such as an E-UTRAN New Radio-Dual Connectivity (ENDC) application.

Multi-path filters disclosed herein can have relatively wide passbands and also provide desirable out-of-band rejection. At the same time, the multi-path filters disclosed herein can achieve relatively low insertion loss and desirable NF. Such features can be advantageous in 5G NR applications. Multi-path filters disclosed herein can meet design specifications for one or more 5G NR operating bands that are challenging to meet with acoustic wave ladder filters.

FIG. 18 is a schematic diagram of one example of a communication network 410. The communication network 410 includes a macro cell base station 411, a small cell base station 413, and various examples of user equipment (UE), including a first mobile device 412a, a wireless-connected car 412b, a laptop 412c, a stationary wireless device 412d, a wireless-connected train 412e, a second mobile device 412f, and a third mobile device 412g. UEs are wireless communication devices. One or more of the macro cell base station 411, the small cell base station 413, or UEs illustrated in FIG. 18 can implement one or more of the multi-path filters in accordance with any suitable principles and advantages disclosed herein. For example, one or more of the UEs shown in FIG. 18 can include one or more multi-path filters in accordance with any suitable principles and advantages disclosed herein.

Although specific examples of base stations and user equipment are illustrated in FIG. 18, a communication network can include base stations and user equipment of a wide variety of types and/or numbers. For instance, in the example shown, the communication network 410 includes the macro cell base station 411 and the small cell base station 413. The small cell base station 413 can operate with relatively lower power, shorter range, and/or with fewer concurrent users relative to the macro cell base station 411. The small cell base station 413 can also be referred to as a femtocell, a picocell, or a microcell. Although the communication network 410 is illustrated as including two base stations, the communication network 410 can be implemented to include more or fewer base stations and/or base stations of other types.

Although various examples of user equipment are shown, the teachings herein are applicable to a wide variety of user equipment, including, but not limited to, mobile phones, tablets, laptops, Internet of Things (IOT) devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 410 of FIG. 18 supports communications using a variety of cellular technologies, including, for example, 4G LTE and 5G NR. In certain implementations, the communication network 410 is further adapted to provide a wireless local area network (WLAN), such as WiFi. Although various examples of communication technologies have been provided, the communication network 410 can be adapted to support a wide variety of communication technologies.

Various communication links of the communication network 410 have been depicted in FIG. 18. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communication that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and Wi-Fi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed Wi-Fi frequencies).

As shown in FIG. 18, the communication links include not only communication links between UE and base stations, but also UE to UE communications and base station to base station communications. For example, the communication network 410 can be implemented to support self-fronthaul and/or self-backhaul (for instance, as between mobile device 412g and mobile device 412f).

The communication links can operate over a wide variety of frequencies. In certain implementations, communications are supported using 5G NR technology over one or more frequency bands that are less than 6 GHz and/or over one or more frequency bands that are greater than 6 GHz. According to certain implementations, the communication links can serve Frequency Range 1 (FR1), Frequency Range 2 (FR2), or a combination thereof. An acoustic wave filter in accordance with any suitable principles and advantages disclosed herein can filter a radio frequency signal within FR1. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 410 can share available network resources, such as available frequency spectrum, in a wide variety of ways. In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 3 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IOT) applications.

The communication network 410 of FIG. 18 can be used to support a wide variety of advanced communication features, including, but not limited to, eMBB, uRLLC, and/or mMTC.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 5 GHz, in a frequency range from about 400 MHz to 8.5 GHZ, or in FR1.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively.

While certain embodiments have been described, these embodiments have been presented by way of example only, and are not intended to limit the scope of the disclosure. Indeed, the novel acoustic filters described herein may be embodied in a variety of other forms. Furthermore, various omissions, substitutions, and changes in the form of the acoustic filters described herein may be made without departing from the spirit of the disclosure. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A multi-path filter for filtering a radio frequency signal, the multi-path filter comprising:
a first signal path from a node of the multi-path filter to an output port of the multi-path filter, the first signal path including a series acoustic wave resonator; and
a second signal path from the node to the output port, the second signal path including a shunt acoustic wave resonator and a phase shifter.

2. The multi-path filter of claim 1 wherein the multi-path filter has a passband formed by at least a combined impedance response of the first signal path and the second signal path.

3. The multi-path filter of claim 2 wherein the passband spans at least 800 megahertz.

4. The multi-path filter of claim 2 wherein the passband has a bandwidth that is at least 20% of a center frequency of the passband.

5. The multi-path filter of claim 2 wherein the passband corresponds to a fifth generation New Radio operating band.

6. The multi-path filter of claim 2 wherein impedances of the first signal path and the second signal path cancel each other outside of the passband to form rejections.

7. The multi-path filter of claim 1 wherein the multi-path filter has a rejection of at least 50 decibels for a Wi-Fi frequency band.

8. The multi-path filter of claim 1 wherein frequency responses of the first signal path and the second signal path combine in a passband of the multi-path filter, and the frequency responses of the first signal path and the second signal path cancel for a rejection band of the multi-path filter that is outside of the passband.

9. The multi-path filter of claim 1 wherein the phase shifter includes a transmission line and a capacitor.

10. The multi-path filter of claim 1 wherein the phase shifter includes a coil inductor and a capacitor.

11. The multi-path filter of claim 1 further comprising a second series acoustic wave resonator coupled between an input port of the multi-path filter and the node.

12. The multi-path filter of claim 1 further comprising a second series acoustic wave resonator and a second shunt acoustic wave resonator, the phase shifter coupled between the second shunt acoustic wave resonator and the output port, and the second series acoustic wave resonator coupled between the shunt acoustic wave resonator and the second shunt acoustic wave resonator.

13. The multi-path filter of claim 1 further comprising a second shunt acoustic wave resonator coupled between the node and ground.

14. The multi-path filter of claim 13 further comprising a second series acoustic wave resonator in series with the series acoustic wave resonator.

15. The multi-path filter of claim 1 wherein the multi-path filter is a receive filter.

16. The multi-path filter of claim 1 wherein the multi-path filter provides a single-ended output signal to the output port.

17. The multi-path filter of claim 1 wherein the series acoustic wave resonator and the shunt acoustic wave resonator are bulk acoustic wave resonators.

18. A multiplexer for filtering radio frequency signals, the multiplexer comprising:
a multi-path filter including a first signal path and a second signal path, the first signal path being from a node of the multi-path filter to an output port of the multi-path filter, the first signal path including a series acoustic wave resonator, the second signal path being from the node to the output port, and the second signal path including a shunt acoustic wave resonator and a phase shifter; and
a second filter coupled to the multi-path filter at a common node.

19. The multiplexer of claim 18 wherein the second filter is a ladder filter that includes acoustic wave resonators.

20. A radio frequency module comprising:
a multi-path filter including a first signal path and a second signal path, the first signal path being from a node of the multi-path filter to an output port of the multi-path filter, the first signal path including a series acoustic wave resonator, the second signal path being from the node to the output port, and the second signal path including a shunt acoustic wave resonator and a phase shifter;
radio frequency circuitry; and
a package structure enclosing the multi-path filter and the radio frequency circuitry.
